(19) United States
(12) Patent Application Publication
(10) Pub. No.: US 2026/0026240 A1
(43) Pub. Date: Jan. 22, 2026

(54) DISPLAY PANEL, DISPLAY MODULE, DISPLAY APPARATUS, AND MANUFACTURING METHOD FOR DISPLAY PANEL

(71) Applicants: Chongqing BOE Display Technology Co., Ltd., Chongqing (CN); BOE Technology Group Co., Ltd., Beijing (CN)

(72) Inventors: Binfeng FENG, Beijing (CN); Yumin LI, Beijing (CN); Fei LI, Beijing (CN); Zhicai XU, Beijing (CN); Zhihong CUI, Beijing (CN); Jiaxiang WANG, Beijing (CN)

(73) Assignees: Chongqing BOE Display Technology Co., Ltd., Chongqing (CN); BOE Technology Group Co., Ltd., Beijing (CN)

(21) Appl. No.: 18/993,100

(22) PCT Filed: Apr. 17, 2024
(86) PCT No.: PCT/CN2024/088420

§ 371 Date: Jan. 10, 2025

(30) Foreign Application Priority Data
May 30, 2023 (CN) 202310629741.5

(51) Int. Cl. H10K 59/80; H10K 59/12; H10K 102/00

(52) U.S. Cl. CPC H10K 59/873; H10K 59/1201; H10K 59/8794; H10K 2102/311

(57) ABSTRACT

The present disclosure discloses a display panel, having a display side and a back side that are disposed opposite each other, and including a display area, a bonding area, and a transition area and a bending area that are located between the display area and the bonding area, where the transition area is located between the bending area and the display area; the display panel further includes: a first substrate, where the first substrate is a rigid substrate, and the first substrate exposes at least the bending area and the bonding area and covers the display area; and a second substrate, disposed on a side of the first substrate that is close to the display side of the display panel; where the second substrate is a flexible substrate; the second substrate exposes at least a part of the display area and covers the bending area and the bonding area.

### CROSS-REFERENCE TO RELATED APPLICATIONS

This application is a national phase entry under 35 USC 371 of International Patent Application No. PCT/CN2024/088420 filed on Apr. 17, 2024, the International Patent Application is filed based on Chinese Patent Application with the application No. 202310629741.5, filed on May 30, 2023, and claims priority to the Chinese Patent Application, the entire contents of the International Patent Application and the Chinese Patent Application are incorporated herein by reference.

### TECHNICAL FIELD

The present disclosure relates to the field of display technologies, and in particular, to a display panel, a display module, a display apparatus, and a manufacturing method for the display panel.

### BACKGROUND

With the rapid development of display technologies, display technologies such as a liquid crystal display apparatus (Liquid Crystal Display, abbreviated as LCD), organic light emitting display apparatus (Organic Light Emitting Display, abbreviated as OLED), quantum dot light emitting display apparatus (Quantum Dot Light Emitting Display, abbreviated as QLED) and mini/micro light emitting display apparatus (Mini/Micro Light Emitting Display, MLED), etc., have been widely penetrated into people's daily lives, and for example, smart phones, wearable watches, televisions, laptops and in-vehicle displays, etc., have gradually spread in people's lives. At present, how to reduce a border of the display apparatus and increase a screen-to-body ratio of the display apparatus has always been the direction of display technology research and development, and the direction of display technology tackling.

### SUMMARY

In an aspect, a display panel is provided. The display panel has a display side and a back side that are disposed opposite each other, where the display panel includes a display area, a bonding area, and a transition area and a bending area that are located between the display area and the bonding area, and the transition area is located between the bending area and the display area.

The display panel further includes a first substrate and a second substrate. The first substrate is a rigid substrate, and the first substrate exposes at least the bending area and the bonding area and covers the display area. The second substrate is disposed on a side of the first substrate that is close to the display side of the display panel, where the second substrate is a flexible substrate. The second substrate exposes at least a part of the display area and covers the bending area and the bonding area. Here, an orthographic projection of the second substrate on a reference plane partially overlaps with an orthographic projection of the first substrate on the reference plane, and the reference plane is a plane in which a surface of the first substrate away from the second substrate is located.

In some embodiments, the first substrate covers the display area and extends to the transition area; the second substrate covers the bending area and the bonding area and extends to the transition area. An orthographic projection of a part of the second substrate located in the transition area on the reference plane overlaps with an orthographic projection of a part of the first substrate located in the transition area on the reference plane.

In some embodiments, the second substrate includes a first part located in the bending area and the bonding area, and a second part located in the transition area, and a width of the first part in a first direction is less than a width of the second part in the first direction. The first direction is roughly parallel to the reference plane and roughly perpendicular to a direction from the display area pointing to the bending area.

In some embodiments, a length of a part in a second direction where the orthographic projection of the second substrate on the reference plane overlaps with the orthographic projection of the first substrate on the reference plane is 0.25 mm to 3 mm. The second direction is roughly parallel to the reference plane and is from the display area pointing to the bending area.

In some embodiments, a thickness of the first substrate is 0.1 mm to 0.55 mm; and/or a thickness of the second substrate is 6 μm to 12.5 μm.

In some embodiments, a material of the first substrate includes one of glass or polymethyl methacrylate; and/or a material of the second substrate includes one of polyimide and saturated polyester.

In some embodiments, in a direction perpendicular to the first substrate and extending from the first substrate pointing to the display side of the display panel, the display panel includes a semiconductor layer, a gate insulating layer, a gate conductive layer, an inter-layer insulating layer, and a first source-drain conductive layer, that are away from the reference plane in sequence; a vertical distance between a part where an orthographic projection of the gate insulating layer on the reference plane overlaps with the second substrate and the reference plane is a first distance, a vertical distance between a part where an orthographic projection of the gate conductive layer on the reference plane overlaps with the second substrate and the reference plane is a second distance, a vertical distance between a part where an orthographic projection of the inter-layer insulating layer on the reference plane overlaps with the second substrate and the reference plane is a third distance, and a vertical distance between a part where an orthographic projection of the first source-drain conductive layer on the reference plane overlaps with the second substrate and the reference plane is a fourth distance; and a vertical distance between a part where the orthographic projection of the gate insulating layer on the reference plane is misaligned with the second substrate and the reference plane is a fifth distance, a vertical distance between a part where the orthographic projection of the gate conductive layer on the reference plane is misaligned with the second substrate and the reference plane is a sixth distance, a vertical distance between a part where the orthographic projection of the inter-layer insulating layer on the reference plane is misaligned with the second substrate and the reference plane is a seventh distance, and a vertical distance between a part where the orthographic projection of the first source-drain conductive layer on the reference plane is misaligned with the second substrate and the reference plane is an eighth distance; where the first distance is smaller than the fifth distance, the second distance is smaller than the sixth distance, the third distance is smaller than the seventh distance, and the fourth distance is smaller than the eighth distance.

In some embodiments, the display panel further includes a first encapsulation layer and a second encapsulation layer. The first encapsulation layer is a rigid encapsulation layer, the first encapsulation layer covers at least the display area, and an orthographic projection of the first encapsulation layer on the reference plane is located within a range of the orthographic projection of the first substrate on the reference plane. The second encapsulation layer is a flexible encapsulation layer, and the second encapsulation layer covers the transition area, the bending area and the bonding area.

In some embodiments, the display panel further includes a third encapsulation layer. The third encapsulation layer is a flexible encapsulation layer; and the third encapsulation layer covers the display area, the transition area, the bending area and the bonding area.

In some embodiments, the display panel further includes a back film. The back film is disposed on a side of the second substrate that is close to the reference plane, and located in the bonding area.

In another aspect, a display module is provided. The display module includes the display panel according to any one of the above embodiments or the above aspect and a heat dissipation stacked layer. The heat dissipation stacked layer is disposed on the back side of the display panel and covers at least the display area. An orthographic projection of the heat dissipation stacked layer on the reference plane is located within a range of the orthographic projection of the first substrate on the reference plane.

In yet another aspect, a display apparatus is provided. The display apparatus includes the display module according to any one of the above embodiments or the above aspect and a casing. The display module is disposed within the casing.

In still yet another aspect, a manufacturing method for a display panel is provided. The manufacturing method for the display panel includes: manufacturing a display motherboard; where the display motherboard has multiple product areas and multiple cutting areas, and a cutting area of the multiple cutting areas is disposed within a bracket of every two adjacent product areas of the multiple product areas; a product area of the multiple product areas includes a display area, a bonding area, and a transition area and a bending area that are located between the display area and the bonding area, and the transition area is located between the bending area and the display area; the display motherboard includes a first substrate motherboard and a second substrate motherboard, the first substrate motherboard is a rigid substrate motherboard and the first substrate motherboard covers the product area and the cutting area; the second substrate motherboard is a flexible substrate motherboard, the second substrate motherboard is located on the first substrate motherboard, and the second substrate motherboard covers at least the bonding area and bending area and exposes at least a part of the display area;
removing a part of the display motherboard located in the cutting area, to obtain multiple sub-display motherboards; where a sub-display motherboard of the multiple sub-display motherboards is located in a product area; and
removing at least a part of the first substrate motherboard of the sub-display motherboard, the part of the first substrate motherboard being located in the bonding area and the bending area, so that a remained part of the first substrate motherboard forms a first substrate and a remained part of the second substrate motherboard forms the second substrate; where the first substrate exposes at least the bending area and the bonding area and covers the display area; the second substrate exposes at least a part of the display area and covers the bending area and the bonding area; an orthographic projection of the second substrate on a reference plane partially overlaps with an orthographic projection of the first substrate on the reference plane; the reference plane is a plane in which a surface of the first substrate away from the second substrate is located.

In some embodiments, manufacturing the display motherboard includes: providing the first substrate motherboard; forming a second initial substrate motherboard on the first substrate motherboard, the second initial substrate motherboard covering the product area and the cutting area; and removing a part of the second initial substrate motherboard located in the display area, so that a remained part of the second initial substrate motherboard forms the second substrate motherboard.

In some embodiments, manufacturing the display motherboard further includes: forming a driving circuit stacked layer and a light-emitting stacked layer on the first substrate motherboard and the second substrate motherboard, the light-emitting layer being located on a side of the driving circuit stacked layer away from the first substrate motherboard; and forming a first encapsulation layer and a second encapsulation layer in sequence on a side of the light-emitting stacked layer away from the first substrate motherboard, where the first encapsulation layer is a rigid encapsulation layer; the first encapsulation layer covers at least the display area, and an orthographic projection of the first encapsulation layer on the reference plane is located within a range of the orthographic projection of the first substrate on the reference plane; the second encapsulation layer is a flexible encapsulation layer, and the second encapsulation layer covers the transition area, the bending area, and the bonding area; or forming a driving circuit stacked layer and a light-emitting stacked layer on the first substrate motherboard and the second substrate motherboard, the light-emitting layer being located on a side of the driving circuit stacked layer away from the first substrate motherboard; and forming a third encapsulation layer on a side of the light-emitting stacked layer away from the first substrate motherboard, where the third encapsulation layer is a flexible encapsulation layer, and the third encapsulation layer covers the product area.

In some embodiments, the manufacturing method further includes: forming a back film on a side of the second substrate that is close to the reference plane; where the back film is located in the bonding area.

In some embodiments, the manufacturing method also includes: removing a part of the second substrate located in the bending area, the bonding area, and a second sub-transition area, so that the part of the second substrate located in the bending area, the bonding area, and the second sub-transition area is reduced in width in a first direction; where the first direction is roughly parallel to the reference plane and roughly perpendicular to a direction from the display area pointing to the bending area, the transition area comprises a first sub-transition area and the second sub-transition area, and the first sub-transition area is located between the second sub-transition area and the display area.

The manufacturing method further includes: in a case where a back film is formed on a side of the second substrate that is close to the reference plane, during removing the part of the second substrate located in the bending area, the bonding area, and the second sub-transition area, further removing a part of the back film located in the bonding area, so that the back film is reduced in width in the first direction.

### BRIEF DESCRIPTION OF THE DRAWINGS

In order to describe technical solutions in the present disclosure more clearly, drawings to be used in some embodiments of the present disclosure will be introduced briefly, and obviously, the drawings in the following description are merely drawings of some embodiments of the present disclosure, and those ordinary skilled in the art may further obtain other drawings according to these drawings. In addition, the drawings in the following description may be regarded as schematic diagrams, and are not limitations on an actual size of a product, an actual procedure of a method and an actual timing of a signal, etc., involved in the embodiments of the present disclosure.

FIG. 1 is a structural diagram of a display apparatus according to some embodiments.

FIG. 2 is a structural diagram of another display apparatus according to some embodiments.

FIG. 3 is a section view along a section line E-E′ in FIG. 1.

FIG. 4 is a structural diagram of a display panel in an unfolded state according to some embodiments.

FIG. 5A is a section view along a section line F-F′ in FIG. 4.

FIG. 5B is another section view along a section line F-F′ in FIG. 4.

FIG. 6A is yet another section view along a section line F-F′ in FIG. 4.

FIG. 6B is further another section view along a section line F-F′ in FIG. 4.

FIG. 7A is yet another section view along a section line F-F′ in FIG. 4.

FIG. 7B is yet another section view along a section line F-F′ in FIG. 4.

FIG. 8A is yet another section view along a section line F-F′ in FIG. 4.

FIG. 8B is yet another section view along a section line F-F′ in FIG. 4.

FIG. 9A is yet another section view along a section line F-F′ in FIG. 4.

FIG. 9B is yet another section view along a section line F-F′ in FIG. 4.

FIG. 10A is yet another section view along a section line F-F′ in FIG. 4.

FIG. 10B is yet another section view along a section line F-F′ in FIG. 4.

FIG. 11A is yet another section view along a section line F-F′ in FIG. 4.

FIG. 11B is yet another section view along a section line F-F′ in FIG. 4.

FIG. 12 is yet another section view along a section line F-F′ in FIG. 4.

FIG. 13 is a section view along a section line Q-Q′ in FIG. 4.

FIG. 14 is a structural diagram of a display module before a display panel is bent according to some embodiments.

FIG. 15 is a structural diagram of another display module after a display panel is bent according to some embodiments.

FIG. 16 to FIG. 17, FIG. 23, and FIG. 28 to FIG. 29 are flowcharts of manufacturing methods of a display panel according to some embodiments.

FIG. 18 to FIG. 22, FIG. 24 to FIG. 26B, and FIG. 30 are flowcharts of manufacturing processes of a display panel according to some embodiments.

FIG. 27A is a structural diagram of a display panel according to some embodiments.

FIG. 27B is a structural diagram of another display panel according to some embodiments.

### DETAILED DESCRIPTION

The technical solutions in some embodiments of the present disclosure will be described clearly and completely with reference to the drawings; obviously, the described embodiments are merely some but not all of the embodiments of the present disclosure. All other embodiments obtained by those ordinary skilled in the art based on the embodiments provided in the present disclosure shall be included in the protection scope of the present disclosure.

Throughout the specification and the claims, the term “comprise/include” and other forms thereof such as the third-person singular form “comprises/includes” and the present participle form “comprising/including” are construed as an open and inclusive meaning, i.e., “including, but not limited to”, unless the context requires otherwise. In the description of the specification, the terms such as “one embodiment”, “some embodiments”, “exemplary embodiments”, “example”, “specific example”, or “some examples”, etc., are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the described specific features, structures, materials, or characteristics may be included in any one or more embodiments or examples in any suitable manner.

Hereinafter, the terms “first” and “second”, etc., are only used for descriptive purposes, and cannot be construed as indicating or implying the relative importance or implicitly indicating the number of indicated technical features. Thus, a feature defined by “first” or “second”, etc., may explicitly or implicitly include one or more of this feature. In the description of the embodiments of the present disclosure, the term “a/the plurality of” or “multiple” means two or more, unless described otherwise.

In the description of some embodiments, the expressions “coupled”, “connected” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium. The term “coupled” indicates that, for example, two or more components are in direct physical or electrical contact with each other. The terms “coupled” or “communicatively coupled” may also mean that two or more components are not in direct contact with each other, but still coordinate or interact with each other. The embodiments disclosed herein are not necessarily limited to the content herein.

The phrase “at least one of A, B, and C” has the same meaning as the phrase “at least one of A, B, or C”, both including the following combinations about A, B, and C: only A, only B, only C, a combination of A and B, a combination of A and C, a combination of B and C, and a combination of A, B, and C.

The phrase “A and/or B” includes the following three combinations: only A, only B, and a combination of A and B.

The use of “applicable to” or “configured to” herein indicates an open and inclusive expression, which does not exclude devices that are applicable to or configured to perform additional tasks or steps.

In addition, the use of the phrase “based on/on the basis of” is meant to be open and inclusive, since a process, step, calculation or other actions that is “based on” one or more of the stated conditions or values may, in practice, be based on additional conditions or values other than those stated.

The term such as “about”, “roughly”, or “approximately” as used herein includes a stated value and an average value within an acceptable deviation range of a particular value, where the acceptable deviation range is determined by those ordinary skilled in the art, considering the measurement(s) in question and error(s) related to the measurement(s) of a particular quantity (i.e., limitation(s) of a measurement system).

The term such as “parallel”, “perpendicular”, or “equal” as used herein includes a stated case and a case similar to the stated case. A range of the similar case is within an acceptable deviation range, where the acceptable deviation range is determined by those ordinary skilled in the art, considering the measurement(s) in question and error(s) related to the measurement(s) of a particular quantity (i.e., limitation(s) of a measurement system). For example, the term “parallel” includes absolute parallelism and approximate parallelism, where an acceptable deviation range of the approximate parallelism may be, for example, a deviation within 5°; the term “perpendicular” includes absolute perpendicularity and approximate perpendicularity, where an acceptable deviation range of the approximate perpendicularity may also be, for example, a deviation within 5°. The term “equal” includes absolute equality and approximate equality, where an acceptable deviation range of the approximate equality may be that, for example, a difference value between the equal two is less than or equal to 5% of any one of the two.

It should be understood that, when a layer or element is referred to as being on another layer or substrate, the layer or element may be directly on the another layer or substrate, or intervening layer(s) may exist between the layer or element and the another layer or substrate.

Exemplary implementations are described herein with reference to section views and/or plane views that are idealized and exemplary drawings. In the drawings, thicknesses of layers and sizes of areas are enlarged for clarity. Thus, variations in shape with respect to the drawings due to, for example, manufacturing technologies and/or tolerances, may be envisaged. Therefore, the exemplary implementations should not be construed as being limited to the shapes of the areas shown herein, but should include shape deviations due to, for example, manufacturing. For example, an etched area shown in a rectangular shape generally has a curved feature. Therefore, the areas shown in the drawings are schematic in nature, and their shapes are not intended to show actual shapes of the areas in a device, and are not intended to limit the scope of the exemplary implementations.

As shown in FIG. 1, some embodiments of the present disclosure provide a display apparatus 1000, and the display apparatus 1000 may be any apparatus that displays either motions (e.g., videos) or stationary (e.g., still images) and either texts or images.

Exemplarily, referring to FIG. 1, the display apparatus 1000 may be any product or component with a display function, such as a television, laptop computer, tablet computer, mobile phone, personal digital assistant (Personal Digital Assistant; abbreviated as PDA), navigator, in-vehicle display, flight display, wearable device, virtual reality (Virtual Reality; abbreviated as VR) device, etc.

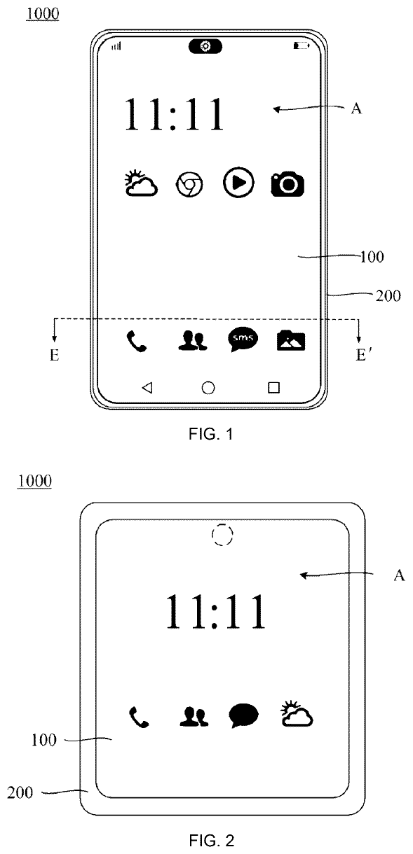

For example, refer to FIG. 2, the display apparatus 1000 may be a wearable device, which may be a rectangular watch as shown in FIG. 2. As shown in FIG. 2, a display area A of the rectangular watch may be roughly rectangular.

For another example, referring to FIG. 1, the display apparatus 1000 may be a mobile phone. As shown in FIG. 1, a display area A of the mobile phone may be roughly rectangular.

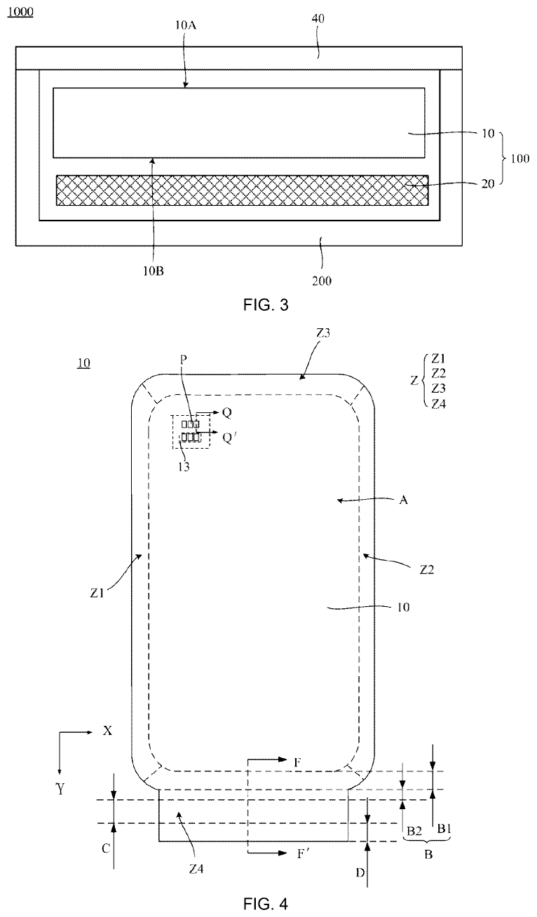

In some embodiments, referring to FIG. 3, the display apparatus 1000 includes a display module 100 and a casing 200, and the display module 100 is disposed within the casing 200.

As shown in FIG. 3, a longitudinal section of the casing 200 may be, for example, U-shaped.

Referring to FIG. 3, the display module 100 may include a display panel 10 and a cover plate 40. The display panel 10 may be, for example, disposed within the casing 200, and the cover plate 40 may be, for example, disposed at an opening of the casing 200.

As shown in FIG. 3, the display panel 10 is configured to display images. The display panel 10 has a display side 10A and a back side 10B that are disposed opposite each other.

It should be noted that the display side 10A refers to a side on which the display panel 10 displays images (an upper side of the display panel 10 in FIG. 3), and the back side 10B refers to another side opposite to the display side 10A (a lower side of the display panel 10 in FIG. 3).

In some embodiments, as shown in FIG. 3, FIG. 14 and FIG. 15, the display module 100 also includes a circuit board 20, and the circuit board 20 may be bonded to the display panel 10 at an end of the display panel 10.

In some embodiments, the display panel 10 may be any one of: an organic light-emitting diode display panel, quantum dot light-emitting diode display panel, micro-light-emitting diode display panel, liquid crystal display panel, plasma display panel, field emission display panel, electrowetting display panel or electrophoretic display panel, etc., and the embodiments of this disclosure do not specifically limit thereto.

The following is a schematic description of some embodiments of the present disclosure by taking the aforementioned display panel 10 being the organic light-emitting diode display panel as an example, but the embodiments of the present disclosure are not limited thereto, and any other display panel may be considered as long as the same technical ideas are applied.

In some related technologies, the display panel is a rigid organic light-emitting diode display panel. Here, a rigid organic light-emitting diode display panel refers to an organic light-emitting diode display panel of which a substrate is a rigid substrate. In the rigid organic light-emitting diode display panel, the circuit board is bonded to the display panel at the end of the display panel, that is, a bonding area is set at an edge of the display panel. Since the rigid substrate cannot be bent, it cannot be implemented that the bonding area at the edge of the display panel is bent toward the back side of the display panel, resulting in a wider border and a lower screen-to-body ratio for the rigid organic light-emitting diode display panel.

In some other related technologies, the display panel is a flexible organic light-emitting diode display panel. Here, the flexible organic light-emitting diode display panel refers to an organic light-emitting diode display panel of which a substrate is a flexible substrate. Although the bonding area at the edge of the display panel may be bent towards the back side, to achieve a narrow border, the strength of the flexible substrate of the flexible organic light-emitting diode display panel is relatively weak. In the related technologies, it is necessary to attach a protective base material on the back side of the flexible organic light-emitting diode display panel, and for example, a titanium alloy and/or high thermal conductivity alloy bracket as a supporting layer is attached on the back side, which significantly increases the production cost of the display panel.

Based on the above, referring to FIG. 4, a display panel 10 provided by some embodiments of the present disclosure includes a display area A and a peripheral area Z disposed on at least one side of the display area A. In FIG. 4, the peripheral area Z disposed around the display area A is taken as an example.

As shown in FIG. 4, the display area A is an area for displaying images, and is configured to dispose multiple pixel units 13.

In some embodiments, referring to FIG. 4, each pixel unit 13 includes multiple sub-pixels P, and each sub-pixel P includes a light-emitting component 14 and a pixel circuit 15 that are electrically connected.

Exemplarily, each pixel unit 13 may include a first sub-pixel with a light-emitting color of a first color, a second sub-pixel with a light-emitting color of a second color, and a third sub-pixel with a light-emitting color of a third color. Here, the first color, the second color, and the third color are three primary colors. For example, the first color is red, the second color is blue, and the third color is green, and the present disclosure is not specifically limited thereto.

As shown in FIG. 4, the peripheral area Z is an area in which no image is displayed, and the peripheral area Z is configured to dispose a display driving circuit, such as a gate driving circuit and a source driving circuit.

Here, the peripheral area Z includes a first border area Z1, a second border area Z2, a third border area Z3, and a fourth border area Z4. Along a first direction X, the first border area Z1 and the second border area Z2 are located on two opposite sides of the display area A; and along a second direction Y, the third border area Z3 and the fourth border area Z4 are located on two other opposite sides of the display area A.

It should be noted that the first direction X and the second direction Y are roughly parallel to a reference plane, and the first direction X and the second direction Y are intersected, for example, the first direction X and the second direction Y are roughly perpendicular. Here, the reference plane is a plane in which the surface of the back side 10B of the display panel 10 is located.

On this basis, the fourth border area Z4 may include, for example, a bonding area D, a transition area B, and a bending area C. Here, the transition area B and the bending area C are located between the display area A and the bonding area D, and the transition area B is located between the bending area C and the display area A. At this point, the second direction Y may be a direction from the display area A pointing to the bending area C.

It should be noted that the bending area C can be bent toward the back side 10B of the display panel 10 along a bending axis extending in the first direction X. The bonding area D is used to bond and connect with the circuit board 20. Here, the bending axis is not an actual structure present in the display panel 10, but is a concept proposed to describe the bending process of the display panel 10.

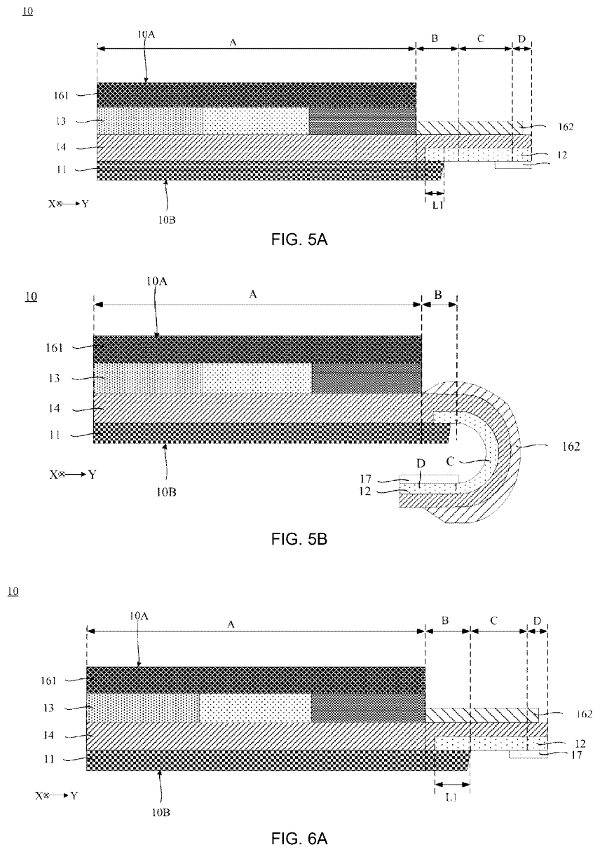

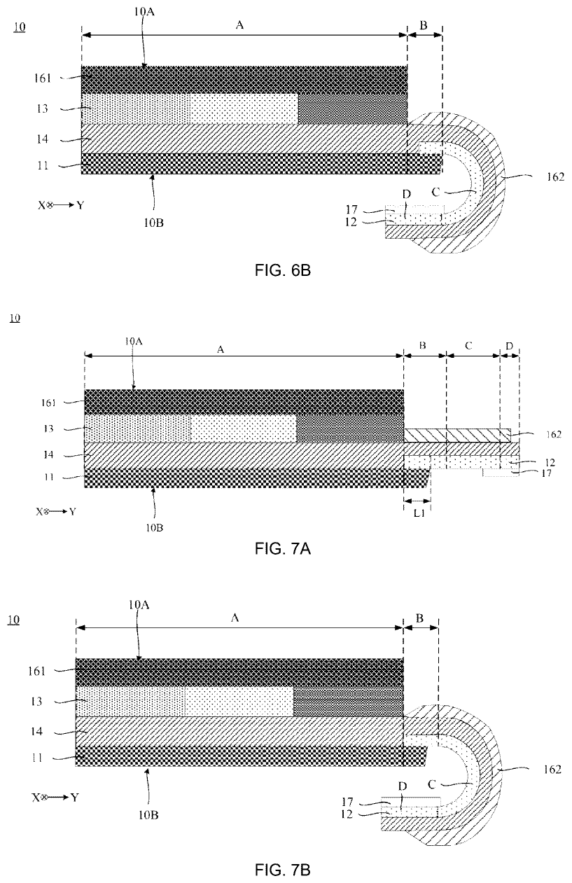

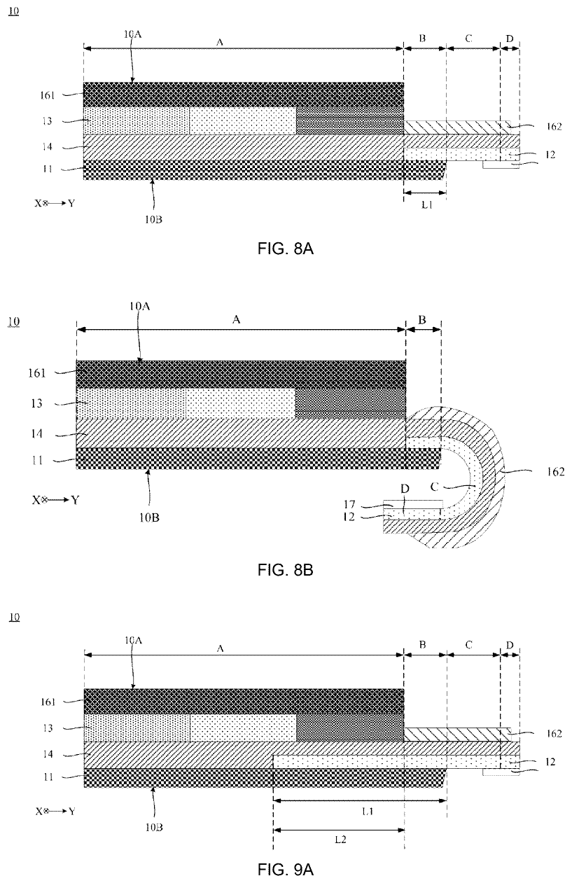

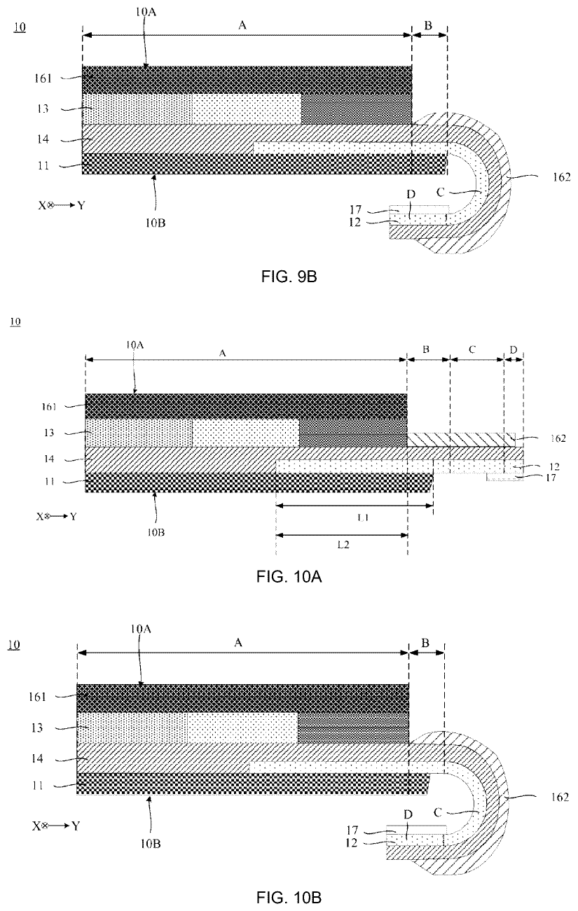

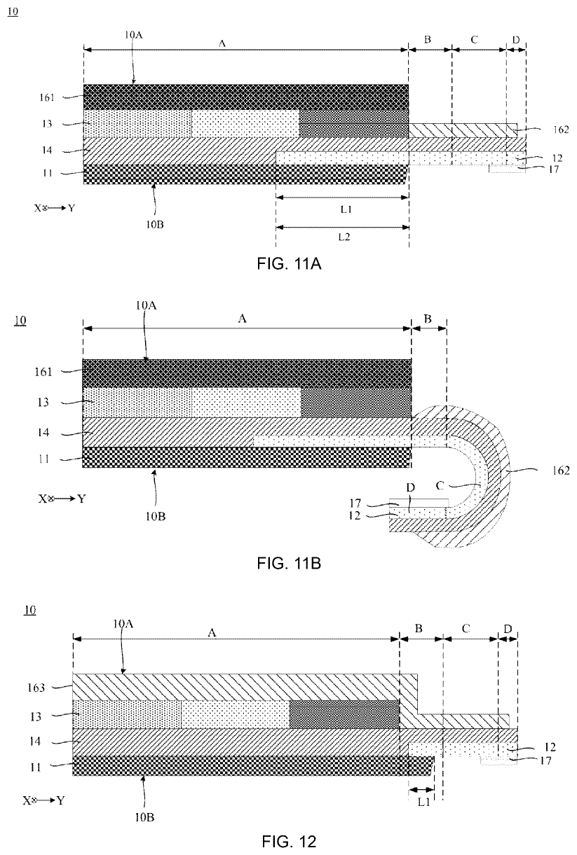

Based on the above, the display panel 10 has two states: an unfolded state and a bent state. The unfolded state is shown in FIG. 5A, FIG. 6A, FIG. 7A, FIG. 8A, FIG. 9A, FIG. 10A, FIG. 11A, FIG. 12, and FIG. 14, and the bent state is shown in FIG. 5B, FIG. 6B, FIG. 7B, FIG. 8B, FIG. 9B, FIG. 10B, FIG. 11B, and FIG. 15. The following descries the location relationship of various portions of the display panel 10 by taking the unfolded state as an example, but the implementations of the present disclosure are not limited thereto.

In some embodiments, as shown in FIG. 5A to FIG. 12, the display panel 10 also includes a first substrate 11 and a second substrate 12. The pixel unit 13 may be disposed on a side of the first substrate 11 away from the reference plane, or the pixel unit 13 may be disposed on a side of both the first substrate 11 and the second substrate 12 away from the reference plane.

Exemplarily, as shown in FIG. 5A to FIG. 12, the first substrate 11 exposes at least the bending area C and the bonding area D, and covers the display area A, and the first substrate 11 is a rigid substrate.

The material of the aforementioned first substrate 11 may include, for example, one of glass or polymethyl methacrylate, but the embodiments of the present disclosure are not limited thereto, and other materials may also be considered.

The thickness of the aforementioned first substrate 11 may be 0.1 mm to 0.55 mm, for example. For example, the thickness of the first substrate 11 may be any one of 0.1 mm, 0.2 mm, 0.3 mm, 0.4 mm, 0.5 mm, or 0.55 mm.

Exemplarily, as shown in FIG. 5A to FIG. 12, the second substrate 12 is disposed on a side of the first substrate 11 that is close to the display side 10A of the display panel 10, and the second substrate 12 is a flexible substrate. The second substrate 12 exposes at least a part of the display area A, and covers the bending area C and the bonding area D.

The material of the aforementioned second substrate 12 may include, for example, one of polyimide or saturated polyester. However, the implementations of the present disclosure are not limited thereto, and other materials may also be considered.

The thickness of the aforementioned second substrate 12 may be, for example, 6 μm to 12.5 μm. For example, the thickness of the second substrate 12 may be any one of 6 μm, 6.2 μm, 6.5 μm, 6.7 μm, 7 μm, 7.4 μm, 8 μm, 8.6 μm, 9 μm, 9.5 μm, 10 μm, 10.5 μm, 11 μm, 11.4 μm, 11.6 μm, 12 μm, 12.5 μm.

Here, an orthographic projection of the second substrate 12 on the reference plane partially overlaps with an orthographic projection of the first substrate 11 on the reference plane. At this point, the reference plane is a plane in which the surface of the first substrate 11 away from the second substrate 12 is located.

In some embodiments, as shown in FIG. 5A to FIG. 8B, the first substrate 11 covers the display area A and extends to the transition area B, while the second substrate 12 covers the bending area C and the bonding area D and extends to the transition area B. An orthographic projection of a part of the second substrate 12 located in the transition area B, on the reference plane, overlaps with an orthographic projection of a part of the first substrate 11 located in the transition area B, on the reference plane.

In some examples, as shown in FIG. 5A and FIG. 5B, the first substrate 11 covers the display area A and a part of the transition area B, and exposes a part of the transition area B, the bend area C, and the bonding area D; and the second substrate 12 covers the bend area C, the bonding area D, and a part of the transition area B, and exposes the display area A and a part of the transition area B.

In some other examples, as shown in FIG. 6A and FIG. 6B, the first substrate 11 covers the display area A and the transition area B, and exposes the bending area C and the bonding area D; and the second substrate 12 covers the bending area C, the bonding area D, and a part of the transition area B, and exposes the display area A and a part of the transition area B.

In some other examples, as shown in FIG. 7A and FIG. 7B, the first substrate 11 covers the display area A and a part of the transition area B, and exposes a part of the transition area B, the bending area C, and the bonding area D; and the second substrate 12 covers the bending area C, the bonding area D, and the transition area B, and exposes the display area A.

In some other examples, as shown in FIG. 8A and FIG. 8B, the first substrate 11 covers the display area A and the transition area B, and exposes the bending area C and the bonding area D; and the second substrate 12 covers the bending area C, the bonding area D and the transition area B, and exposes the display area A.

In some other embodiments, referring to FIG. 9A to FIG. 11B, the first substrate 11 covers the display area A, and the second substrate 12 covers the transition area B, the bending area C, and the bonding area D, and extends to the display area A. Also, an orthographic projection of a part of the second substrate 12 located in the display area A on the reference plane overlaps with an orthographic projection of a part of the first substrate 11 located in the display area A on the reference plane.

In some examples, as shown in FIG. 9A and FIG. 9B, the first substrate 11 covers the display area A and the transition area B, and exposes the bending area C and the bonding area D; the second substrate 12 covers the bending area C, the bonding area D, the transition area B, and a part of the display area A, and exposes a part of the display area A.

In some other examples, as shown in FIG. 10A and FIG. 10B, the first substrate 11 covers the display area A and a part of the transition area B, and exposes a part of the transition area B, the bend area C, and the bonding area D; and the second substrate 12 covers the bend area C, the bonding area D, the transition area B, and a part of the display area A, and exposes a part of the display area A.

In some other examples, as shown in FIG. 11A and FIG. 11B, the first substrate 11 covers the display area A and exposes the transition area B, the bending area C, and the bonding area D; and the second substrate 12 covers the bending area C, the bonding area D, the transition area B, and a part of the display area A, and exposes a part of the display area A.

Accordingly, in the display panel 10 provided in some embodiments of the present disclosure, the first substrate 11 (rigid substrate) exposes the bending area C and bonding area D, and the second substrate 12 (flexible substrate) covers the bending area C and bonding area D and exposes at least a part of the display area A.

Firstly, through a bending process, the bending area C may be bent toward the back side 10B of the display area A of the display panel 10, along the bending axis extending in the first direction X, so that the bonding area D is bent to the back side 10B of the display area of the display panel 10, enabling that the bonding area D at the edge of the display panel 10 is bent toward the back side 10B, thereby reducing the border of the display apparatus 1000 and increasing the screen-to-body ratio of the display apparatus 1000.

Secondly, since the display area A of the display panel 10 is covered with the first substrate 11 (rigid substrate), the display panel 10 has good strength and high applicability, and for example, it is applicable for middle-size or large-size products (>7 inches), such as in scenarios of transportation display, medical display, and instrumentation device. Also, compared with related technologies, there is no need to attach an expensive support layer on the back side of the display panel 10, so that the production cost for the display panel 10 is lower. At the same time, the process step of attaching the support layer on the back side of the display panel 10 is reduced, the manufacturing process procedure of the display panel 10 is simplified, and the yield of the display panel 10 is improved.

Thirdly, since the second substrate 12 exposes at least a part of the display area A, the influence of the second substrate 12 on the channel charge transfer of the pixel circuit 15 of the pixel unit 13 may be reduced, thereby improving the stability of the pixel circuit 15 of the pixel unit 13, and thus improving the display afterimage phenomenon of the display panel 10.

In addition, since the orthographic projection of the second substrate 12 on the reference plane partially overlaps with the orthographic projection of the first substrate 11 on the reference plane, that is, the second substrate 12 is close to the edge of the first substrate 11, and extends inside the edge of the first substrate 11. With this disposing, the risk of fracture of the film layer at the junction between the second substrate 12 and the first substrate 11 may be reduced.

In some embodiments, referring to FIG. 5A, FIG. 6A, FIG. 7A, FIG. 8A, FIG. 9A, FIG. 10A, FIG. 11A and FIG. 12, a length L1 of a part in the second direction Y where the orthographic projection of the second substrate 12 on the reference plane overlaps with the orthographic projection of the first substrate 11 on the reference plane is 0.25 mm to 3 mm.

For example, a length L1 of a part in the second direction Y where the orthographic projection of the second substrate 12 on the reference plane overlaps with the orthographic projection of the first substrate 11 on the reference plane may be any one of 0.25 mm, 0.28 mm, 0.3 mm, 0.32 mm, 0.4 mm, 0.46 mm, 0.5 mm, 0.6 mm, 0.7 mm, 0.8 mm, 0.9 mm, 1.0 mm, 1.2 mm, 1.5 mm, 1.8 mm, 2.0 mm, 2.2 mm, 2.4 mm, 2.6 mm, 2.8 mm, 2.9 mm, 3.0 mm.

In this disposing manner, on the one hand, the risk of separation between the first substrate 11 and the second substrate 12 can be reduced, and on the other hand, the influence of the second substrate 12 on the channel charge transfer of the pixel circuit 15 may be avoided, so as to improve the display afterimage phenomenon of the display panel 10.

In some embodiments, referring to FIG. 9A, FIG. 10A and FIG. 11A, a maximum length L2 of a part of the second substrate 12 located at the display area A in the second direction Y is smaller than a maximum length of a pixel unit 13 in the second direction Y.

In this way, the influence of the second substrate 12 on the channel charge transfer of the pixel circuit 15 of the display area A may be avoided, so as to improve the display afterimage phenomenon of the display panel 10.

In some embodiments, referring to FIG. 4, the transition area B includes a first sub-transition area B1 and a second sub-transition area B2, and the first sub-transition area B1 is located between the second sub-transition area B2 and the display area A. Here, a width of the first sub-transition area B1 in the first direction X is greater than a width of the second sub-transition area B2 in the first direction X.

In some examples, referring to FIG. 4 to FIG. 8B, the second substrate 12 includes a first part and a second part. The first part is located in the second sub-transition area B2, the bending area C, and the bonding area D; and the second part is located in the first sub-transition area B1. Here, a width of the first part in the first direction X is less than a width of the second part in the first direction X.

In this disposing manner, a part of the second substrate 12 located in the bending area C may be narrowed, so as to reduce the stress generated in the bending area C in the bending process, so that the stress generated in the bending area C is less than a safety value, thereby reducing or even avoiding the generation of problems such as cracking in the bending area C.

In some other examples, referring to FIG. 4, and FIG. 9A to FIG. 11B, the second substrate 12 includes a first part and a third part. The first part is located in the second sub-transition area B2, the bending area C, and the bonding area D; and the third part is located in the first sub-transition area B1 and the display area A. Here, a width of the first part in the first direction X is less than a width of the third part in the first direction X.

In this disposing manner, a part of the second substrate 12 located in the bending area C may be narrowed, so as to reduce the stress generated in the bending area C in the bending process, so that the stress generated in the bending area C is less than the safety value, thereby reducing or even avoiding the generation of problems such as cracking in the bending area C.

In some embodiments, referring to FIG. 5A to FIG. 11B, the display panel 10 also includes a first encapsulation layer 161 and a second encapsulation layer 162. The first encapsulation layer is a rigid encapsulation layer, and the first encapsulation layer covers at least the display area A, and an orthographic projection of the first encapsulation layer 161 on the reference plane is within a range of the orthographic projection of the first substrate 11 on the reference plane. The second encapsulation layer 162 is a flexible encapsulation layer, and the second encapsulation layer 162 covers the transition area B, the bending area C, and the bonding area D.

Exemplarily, the first encapsulation layer 161 may include an encapsulation cover plate and a sealing layer, the encapsulation cover plate is located on a side of the first substrate 11 away from the reference plane, and the sealing layer is located between the encapsulation cover plate and the first substrate 11. Here, the material of the encapsulation cover plate may include glass, for example. The material of the sealing layer may include glass powder, for example.

Exemplarily, the second encapsulation layer 162 may include at least one inorganic layer. The material of the second encapsulation layer 162 may include, for example, at least one of aluminum oxide, titanium dioxide, tantalum dioxide, hafnium dioxide, zinc oxide, silicon dioxide, silicon nitride, or silicon oxynitride.

In some other embodiments, referring to FIG. 12, the display panel 10 also includes a third encapsulation layer 163, and the third encapsulation layer 163 is a flexible encapsulation layer. The third encapsulation layer 163 covers the display area A, the transition area B, the bending area C and the bonding area D.

Exemplarily, the third encapsulation layer 163 may include a first inorganic encapsulation layer 1631, an organic encapsulation layer 1632, and a second inorganic encapsulation layer 1633 stacked in sequence in the direction away from the first substrate 11. Here, the organic encapsulation layer 1632 covers the display area A, extends to the transition area B, and does not cover the bending area C. The first inorganic encapsulation layer 1631 and the second inorganic encapsulation layer 1633 cover the display area A, the transition area B, and the bending area C, and extend to the bonding area D.

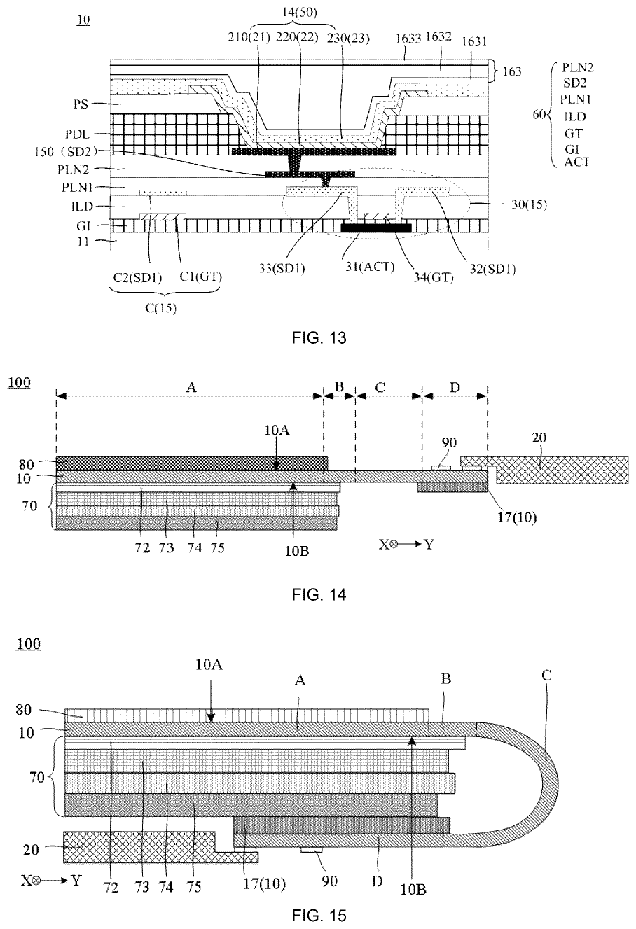

FIG. 13 is a section view along the section line Q-Q′ in FIG. 4. The following exemplarily describes other film layers between the substrate (the first substrate 11 and the second substrate 12) and the encapsulation layer (the first encapsulation layer 161 or the third encapsulation layer 163) in the display panel 10 in the embodiments of the present disclosure.

In some embodiments, referring to FIG. 13, the display panel 10 includes a driving circuit stacked layer 60 (driving circuit layer 60) and a light-emitting stacked layer 50.

As shown in FIG. 13, in the direction perpendicular to the first substrate 11 and from the first substrate 11 pointing to the encapsulation layer (the third encapsulation layer 163), the driving circuit stacked layer 60 includes a semiconductor layer ACT, a gate insulating layer GI, a gate conductive layer GT, an inter-layer insulating layer ILD, a first source-drain conductive layer SD1, a first flat layer PLN1, a second source-drain conductive layer SD2, and a second flat layer PLN2, which are away from the reference plane in sequence.

Here, referring to FIG. 13, the pixel circuit 15 includes multiple thin-film transistors 30 and storage capacitors C. The storage capacitor C includes a first capacitor electrode C1 and a second capacitor electrode C2. The thin-film transistor 30 includes a semiconductor channel 31, a source 32, a drain 33, and a gate 34, and the source 32 and the drain 33 contact with the semiconductor channel 31 respectively.

On this basis, as shown in FIG. 13, the semiconductor layer ACT includes the semiconductor channel 31 of the thin-film transistor 30. The gate conductive layer GT includes the gate 34 of the thin-film transistor 30 and the first capacitor electrode C1 of each capacitor C. The first source-drain conductive layer SD1 includes the source 32 and the drain 33 of the thin-film transistor 30, as well as the second capacitor electrode C2 of each capacitor C. The second source-drain conductive layer SD2 may include a transfer electrode 150.

Based on the above, referring to FIG. 13 and FIG. 5A, a vertical distance between a part where an orthographic projection of the gate insulating layer GI on the reference plane overlaps with the second substrate 12 and the reference plane is a first distance; a vertical distance between a part where an orthographic projection of the gate conductive layer GT on the reference plane overlaps with the second substrate 12 and the reference plane is a second distance; a vertical distance between a part where an orthographic projection of the inter-layer insulating layer ILD on the reference plane overlaps with the second substrate 12 and the reference plane is a third distance; and a vertical distance between a part where an orthographic projection of the first source-drain conductive layer SD1 on the reference plane overlaps with the second substrate 12 and the reference plane is a fourth distance. A vertical distance between a part where the orthographic projection of the gate insulating layer GI on the reference plane is misaligned with the second substrate 12 and the reference plane is a fifth distance; a vertical distance between a part where the orthographic projection of the gate conductive layer GT on the reference plane is misaligned with the second substrate 12 and the reference plane is a sixth distance; a vertical distance between a part where the orthographic projection of the inter-layer insulating layer ILD on the reference plane is misaligned with the second substrate 12 and the reference plane is a seventh distance; and a vertical distance between a part where the orthographic projection of the first source-drain conductive layer SD1 on the reference plane is misaligned with the second substrate 12 and the reference plane is an eighth distance.

Here, the first distance is smaller than the fifth distance, the second distance is smaller than the sixth distance, the third distance is smaller than the seventh distance, and the fourth distance is smaller than the eighth distance.

In some embodiments, as shown in FIG. 13, in the direction perpendicular to the first substrate 11 and from the first substrate 11 pointing to the encapsulation layer (the third encapsulation layer 163), the light-emitting stacked layer 50 includes a first electrode layer 21, a light-emitting function layer 22 and a second electrode layer 23.

In some examples, the light-emitting function layer 22 includes only a light-emitting layer. In some other examples, the light-emitting function layer 22 includes at least one of an electronic transporting layer (electron transporting layer, abbreviated as: ETL), an electronic injection layer (electron injection layer, abbreviated as: EIL), a hole transporting layer (abbreviated as: HTL), and a hole injection layer (abbreviated as: HIL), in addition to the light-emitting layer.

Here, as shown in FIG. 13, the light-emitting component 14 includes a first electrode 210, a light-emitting portion 220, and a second electrode 230, the first electrode 210 is electrically connected to the source 32 or the drain 33 of one of multiple thin-film transistors 30, and it is schematically illustrated in FIG. 13 with the first electrode 210 being electrically connected to the drain 33 of the transistor 30. Here, the transfer electrode 150 electrically contacts with the first electrode 210 and the drain 33, to ensure that the first electrode 210 is electrically connected with the drain 33.

It should be noted that the first electrode 210 is a positive electrode of the light-emitting component 14, and the second electrode 230 is a negative electrode of the light-emitting component 14. Alternatively, the first electrode 210 is a negative electrode of the light-emitting component 14, and the second electrode 230 is a positive electrode of the light-emitting component 14. It is schematically illustrated in FIG. 13 with the first electrode 210 being the positive electrode of the light-emitting component 14 and the second electrode 230 being the negative electrode of the light-emitting component 14.

On this basis, the first electrode layer 21 includes the first electrode 210 of the light-emitting component 14, the second electrode layer 23 includes the second electrode 230 of the light-emitting component 14, and the light-emitting function layer 22 includes the light-emitting portion 220 of the light-emitting component 14.

In some embodiments, referring to FIG. 13, the display panel 10 also includes a pixel definition layer PDL, the pixel definition layer PDL includes multiple opening areas, and a light-emitting component 14 is disposed in an opening area.

In some embodiments, referring to FIG. 13, the display panel 10 also includes a photo spacer PS, and the photo spacer PS is disposed between the pixel definition layer PDL and the light-emitting function layer 22.

In some embodiments, referring to FIG. 5A to FIG. 12 and FIG. 14 to FIG. 15, the display panel 10 also includes a back film 17, disposed on a side of the second substrate 12 close to the reference plane, and located in the bonding area D. That is, the back film 17 is located on the back side 10B of the display panel 10. In this way, the back film 17 disposed on the back side 10B of the display panel 10 may provide support to the second substrate 12, thereby reducing the risk of flexing or wrinkling in the bonding area D of the display panel 10.

In some embodiments, referring to FIG. 14 and FIG. 15, the above display module 100 also includes an anti-reflective layer 80, and the anti-reflective layer 80 is located on a side of the display panel 10 away from the reference plane.

As shown in FIG. 14 and FIG. 15, the edge of the display area A is located within a range of an edge of an orthographic projection of the anti-reflective layer 80 on the reference plane, to enhance the ability of the whole display area A to resist the interference of external ambient light. For example, the anti-reflective layer 80 may fully cover the display area A and extend to the bending area B.

In some examples, the display panel 10 includes the third encapsulation layer 163, and at this point, the anti-reflective layer 80 may be directly formed on a side of the third encapsulation layer 163 away from the reference plane through a semiconductor process. The anti-reflective layer 80 may include a polarizer. In this way, light passing through a certain polarization direction is selected by means of the polarizer, so that the reflection intensity of external ambient light on the display panel 10 may be reduced.

In some other examples, the display panel 10 includes the first encapsulation layer 161 and the second encapsulation layer 162, and at this point, the aforementioned anti-reflective layer 80 may be indirectly formed on a side of the first encapsulation layer 161 away from the reference plane through an adhesive process. The anti-reflective layer 80 may include a black matrix and a color film. The black matrix is used to separate light emitted from different sub-pixels P, and reduce the reflected light of external ambient light entering the inside of the display panel 10. The color film may filter out most wavebands of light from external ambient light, thereby reducing the reflection intensity of the external ambient light on the display panel 10.

In some embodiments, referring to FIG. 14 and FIG. 15, the display module 100 also includes a heat dissipation stacked layer 70, and the heat dissipation stacked layer 70 is disposed on the back side 10B of the display panel 10, and at least covers the display area A; also, an orthographic projection of the heat dissipation stacked layer 70 on the reference plane is within a range of the orthographic projection of the first substrate 11 on the reference plane.

In some embodiments, referring to FIG. 14 and FIG. 15, the aforementioned heat dissipation stacked layer 70 may include, for example, a first adhesive layer 72, a first buffer layer 73, a first protective layer 74 and a heat dissipation layer 75, that are stacked in sequence.

It should be noted that, for example, adhesive glue layers may also be disposed between the first buffer layer 73, the first protective layer 74, and the heat dissipation layer 75, but the embodiments of the present disclosure are not specifically limited thereto. Additionally, in some other examples, the first protective layer 74 may not be disposed in the aforementioned heat dissipation stacked layer 70, but the embodiments of the present disclosure are not specifically limited thereto.

Referring to FIG. 14 and FIG. 15, an orthographic projection of the first adhesive layer 72 on the reference plane may be grid-like, for example. The grid-like structure of the first adhesive layer 72 may prevent bubbles from forming in the adhesive process of the first adhesive layer 72 and the display panel 10, and avoid adverse effects such as bulging of the film layer of the display panel 10, etc.

It should be noted that the material of the aforementioned first adhesive layer 72 includes a glue layer. For example, the material of the first adhesive layer 72 includes optical glue and/or pressure-sensitive glue, but the embodiments of the present disclosure are not specifically limited thereto.

Here, referring to FIG. 14 and FIG. 15, an orthographic projection of the edge of the first adhesive layer 72 on the reference plane may be, for example, located within a range of an orthographic projection of the edge of the display area A and the transition area B on the reference plane.

Referring to FIG. 14 and FIG. 15, the first buffer layer 73 mainly serves as a buffering and anti-vibration function, so as to improve the ability of the display apparatus 1000 to resist impact.

Here, referring to FIG. 14 and FIG. 15. An orthographic projection of the edge of the first buffer layer 73 on the reference plane may be, for example, located within a range of an orthographic projection of the edge of the display area A and the transition area B on the reference plane.

In addition, the first buffer layer 73 may be a single-layer or multi-layer stacked structure, and the first buffer layer 73 may include at least one of a polyimide (Polyimide, abbreviated as PI) layer, a polyphenylene terephthalate (Polyethylene terephthalate, abbreviated as PET) plastic layer and a foam layer.

Exemplarily, the first buffer layer 73 may also be composed of PET plastic together with graphite; for example, a support frame is formed by using PET plastic and graphite is filled inside the support frame. In this way, the first buffer layer 73 may also serve as a heat dissipation function.

Referring to FIG. 14 and FIG. 15, the first protective layer 74 mainly serves to release stress, and the first protective layer 74 may deform relatively after being subjected to stress (pull stress or pressure stress), and release its internal rebound stress by the deformation of the first protective layer 74 itself, thereby reducing the possibility of the film layer being separated in the display panel 10.

Here, referring to FIG. 14 and FIG. 15, an orthographic projection of an edge of the first protective layer 74 on the reference plane is located within a range of the orthographic projection of the edge of the display area A and the transition area B on the reference plane.

Exemplarily, referring to FIG. 14 and FIG. 15, the orthographic projection of the edge of the first protective layer 74 on the reference plane is located between the orthographic projection of the edge of the display area A and the transition area B on the reference plane and the orthographic projection of the edge of the first buffer layer 73 on the reference plane.

Referring to FIG. 14 and FIG. 15, the heat dissipation layer 75 may be a single-layer or multi-layer stacked structure. The heat dissipation layer 75 may include a metal; for example, the heat dissipation layer 75 includes at least one of copper, argentum, and steel. The heat dissipation layer 75 may also include a non-metal; for example, the heat dissipation layer 75 includes graphite.

Here, referring to FIG. 14 and FIG. 15, the orthographic projection of the edge of the heat dissipation layer 75 on the reference plane is located within a range of the orthographic projection of the edge of the display area A and the transition area B on the reference plane.

Exemplarily, referring to FIG. 14 and FIG. 15, the orthographic projection of the edge of the heat dissipation layer 75 on the reference plane is located within a range of the orthographic projection of the edge of the first protective layer 74 on the reference plane.

In addition, the aforementioned heat dissipation layer 75 may also be electrically connected to the casing 200, and the heat dissipation layer 75 may conduct heat or charge to the casing 200, and implement the grounding of the heat dissipation layer 75, thereby facilitating the heat dissipation of the heat dissipation layer 75.

In some embodiments, referring to FIG. 14 and FIG. 15, the display module 100 also includes a driving chip 90. Here, the driving chip 90 is configured to provide the display panel 10 with data signals required for displaying pictures.

Exemplarily, as shown in FIG. 14 and FIG. 15, the driving chip 90 may be disposed in the bonding area D. In this way, the driving chip 90 may provide the display area A with data signals required for displaying pictures through the bonding area D, the bending area C and the transition area B, to control the display panel 10 to display images.

Herein, the driving chip 90 includes at least one of microchips such as a source driving chip, a touch chip, a timing controller and a gamma circuit, but the embodiments of the present disclosure are not specifically limited thereto.

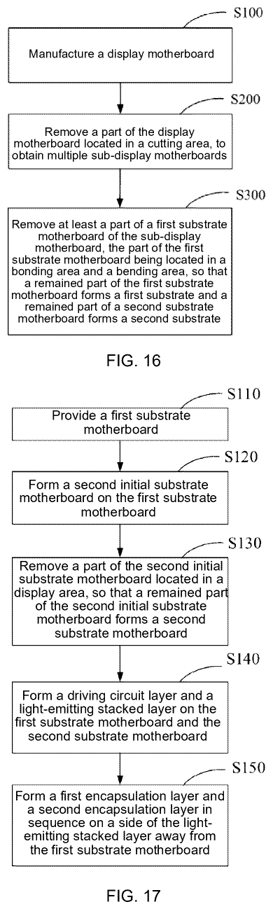

The embodiments of the present disclosure also provide a manufacturing method for a display panel 10, for manufacturing the display panel 10 described in any of the embodiments above. Referring to FIG. 16, the manufacturing method includes S100 to S300.
S100: manufacture a display motherboard 1.

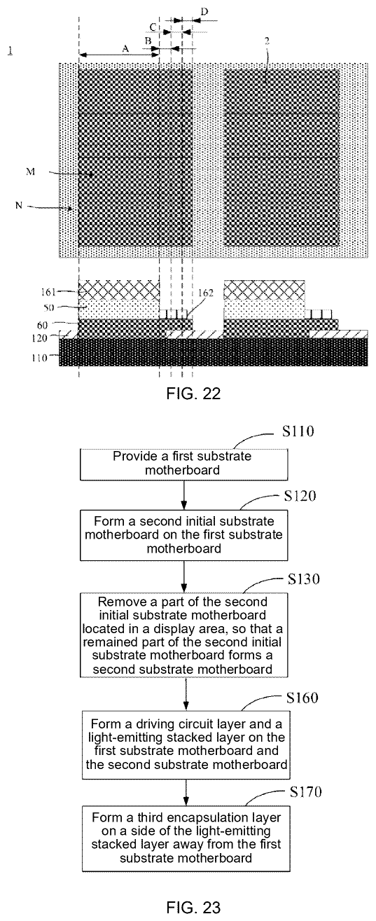

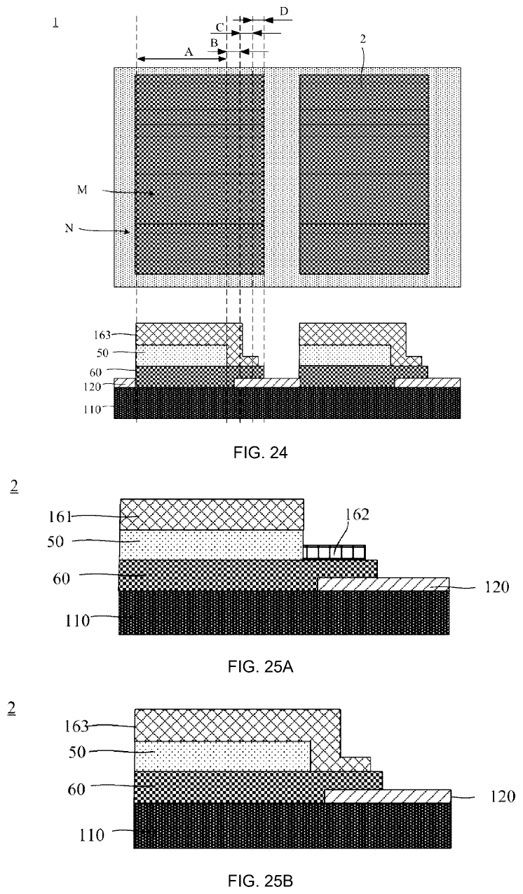

In the above step, referring to FIG. 22, the display motherboard 1 has multiple product areas M and multiple cutting areas N, and a cutting area N is disposed within a bracket of every two adjacent product areas M. Referring to FIG. 22, the product area includes the display area A, the bonding area D, and the transitional area B and bending area C located between the display area A and the bonding area D; and the transition area B is located between the bending area C and the display area A.

As shown in FIG. 22, the display motherboard 1 includes a first substrate motherboard 110 and a second substrate motherboard 120. The first substrate motherboard 110 is a rigid substrate motherboard, and the first substrate motherboard 110 covers the product areas M and the cutting area N. The second substrate motherboard 120 is a flexible substrate motherboard, and the second substrate motherboard 120 is located on the first substrate motherboard 110. The second substrate motherboard 120 covers at least the bonding area D and the bending area C and exposes at least a part of the display area A.

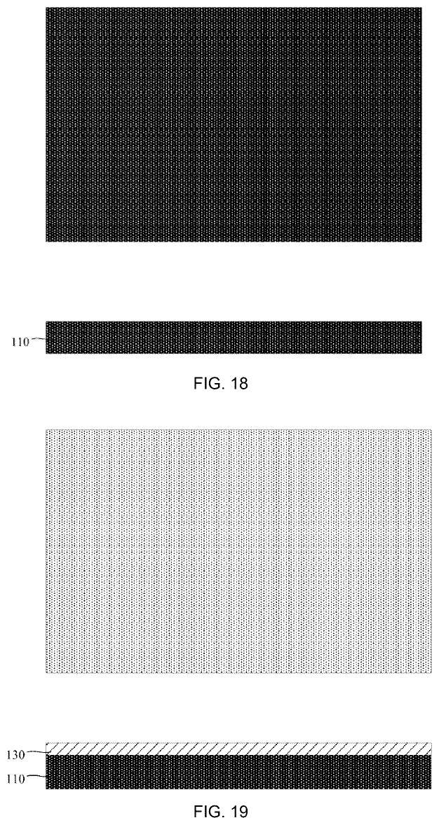

In some examples, referring to FIG. 17, S100 includes S110 to S130.
S110: referring to FIG. 18, provide a first substrate motherboard 110.

In the above step, the first substrate motherboard 110 is a rigid substrate motherboard. Exemplarily, the material of the first substrate motherboard 110 may include one of glass or polymethyl methacrylate. However, the embodiments of the present disclosure are not limited thereto, and other materials may also be considered.
S120: referring to FIG. 19, form a second initial substrate motherboard 130 on the first substrate motherboard 110.

In the above step, referring to FIG. 19, the second initial substrate motherboard 130 covers the first substrate motherboard 110, that is, the second initial substrate motherboard 130 covers the product areas M and the cutting area N.

Exemplarily, the second initial substrate motherboard 130 is formed on the first substrate motherboard 110 by a coating process.

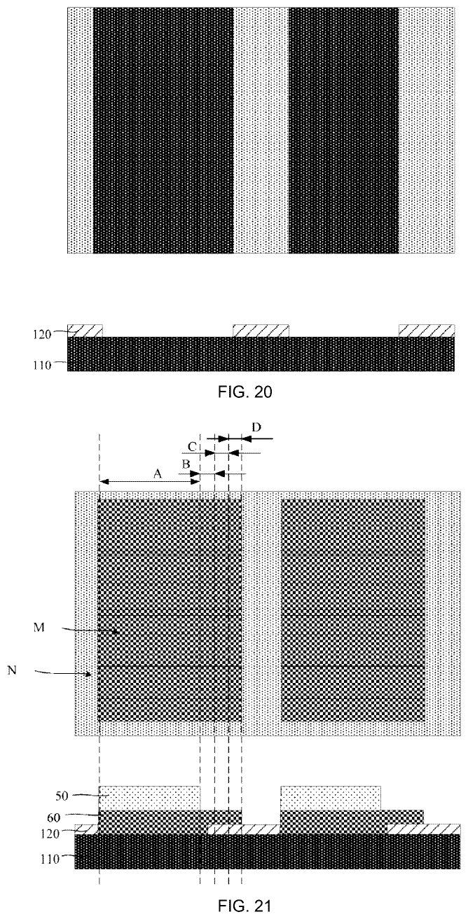

Here, the second initial substrate motherboard 130 is a flexible initial substrate motherboard. Exemplarily, the material of the second initial substrate motherboard 130 may include one of polyimide or saturated polyester. However, the embodiments of the present disclosure are not limited thereto, and other materials may also be considered.
S130: referring to FIG. 20, remove a part of the second initial substrate motherboard 130 located in the display area A, so that a remaining part of the second initial substrate motherboard 130 forms a second substrate motherboard 120.

Exemplarily, the part of the second initial substrate motherboard 130 located in the display area A is removed by an etching process.

In some examples, referring to FIG. 17, S100 also includes S140 to S150.
S140: referring to FIG. 21, form a driving circuit stacked layer 60 and a light-emitting stacked layer 50 on the first substrate motherboard 110 and the second substrate motherboard 120.

In the above step, as shown in FIG. 21, the light-emitting stacked layer 50 is located on a side of the driving circuit stacked layer 60 away from the first substrate motherboard.

Exemplarily, the driving circuit stacked layer 60 is formed by a coating process and an exposure process, etc. The light-emitting stacked layer 50 is formed by an evaporation process or an ink-jet printing process.
S150: referring to FIG. 22, form a first encapsulation layer 161 and a second encapsulation layer 162 in sequence on a side of the light-emitting stacked layer 50 away from the first substrate motherboard 110.

In the above step, referring to FIG. 22, the first encapsulation layer 161 is a rigid encapsulation layer, the first encapsulation layer 161 at least covers the display area A, and an orthographic projection of the first encapsulation layer 161 on the reference plane is located within a range of an orthographic projection of the first substrate 11 on the reference plane. The second encapsulation layer 162 is a flexible encapsulation layer, and the second encapsulation layer 162 covers the transition area B, the bending area C, and the bonding area D.

In some other examples, referring to FIG. 23, S100 also includes S160 to S170.
S160: referring to FIG. 21, form a driving circuit stacked layer 60 and a light-emitting stacked layer 50 on the first substrate motherboard 110 and the second substrate motherboard 120.

In the above step, as shown in FIG. 21, the light-emitting stacked layer 50 is located on the side of the driving circuit stacked layer 60 away from the first substrate motherboard 110.

Exemplarily, the driving circuit stacked layer 60 is formed by a coating process, an exposure process, and an exposure process, etc. The light-emitting stacked layer 50 is formed by an evaporation process or an ink-jet printing process.
S170: referring to FIG. 24, form a third encapsulation layer 163 on a side of the light-emitting stacked layer 50 away from the first substrate motherboard 110.

In the above step, as shown in FIG. 24, the third encapsulation layer 163 is a flexible encapsulation layer, and the third encapsulation layer covers the product areas M.
S200: referring to FIG. 22 and FIG. 24, remove a part of the display motherboard located in the cutting area N, to obtain multiple sub-display motherboards 2 shown in FIG. 25A or FIG. 25B.

In the step above, referring to FIG. 22 and FIG. 24, a sub-display motherboard 2 is located in a product area M.

S300: referring to FIG. 26A and FIG. 26B, remove at least a part of the first substrate motherboard 110 of the sub-display motherboard 2, the part of the first substrate motherboard 110 being located in the bonding area D and the bending area C, so that a remained part of the first substrate motherboard 110 forms the first substrate 11 and a remained part of the second substrate motherboard 120 forms the second substrate 12.

In the above step, referring to FIG. 26A and FIG. 26B, the first substrate 11 exposes at least the bending area C and bonding area D, and covers the display area A; and the second substrate 12 exposes at least a part of the display area A, and covers the bending area C and the bonding area D. The orthographic projection of the second substrate 12 on the reference plane partially overlaps with the orthographic projection of the first substrate 11 on the reference plane. The reference plane is a plane in which the surface of the first substrate 11 away from the second substrate 12 is located.

It should be understood that the beneficial effects of the manufacturing method for the display panel 10 mentioned above are the same as those of the display panel 10 described in any of the embodiments mentioned above, so they will not be repeated.

In some embodiments, referring to FIG. 28, the manufacturing method also includes S400.
S400: referring to FIG. 30, remove a part of the second substrate 12 located in the bending area C, the bonding area D and a second sub-transition area B2, so that the part of the second substrate 12 located in the bending area C, the bonding area D and the second sub-transition area B2 is reduced in width in a first direction X.

Here, the first direction X is roughly parallel to the reference plane, and roughly perpendicular to a direction from the display area A pointing to the bending area C.

Exemplarily, the part of the second substrate 12 located in the bending area C, the bonding area D and the second sub-transition area B2 is removed by laser cutting.

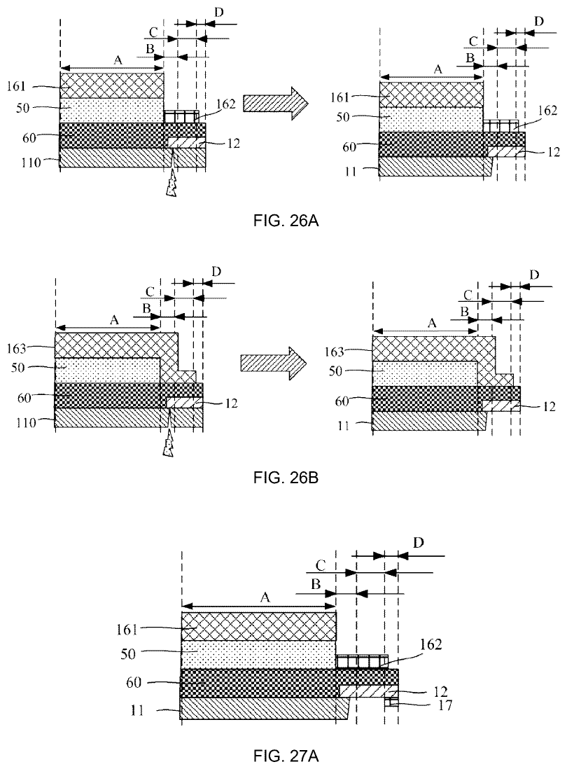

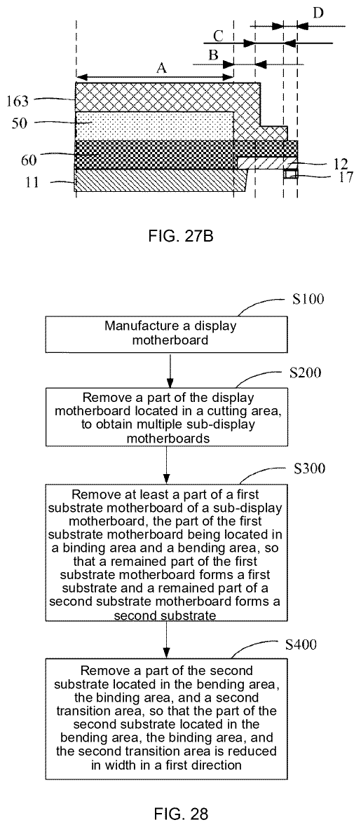

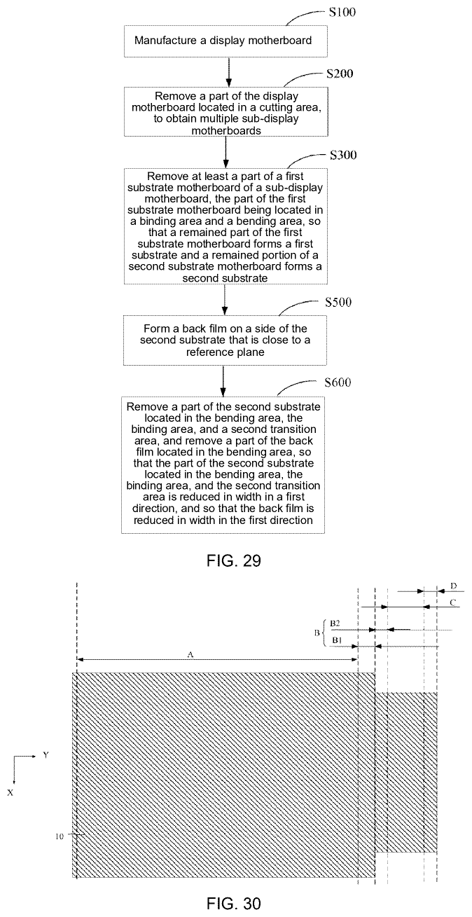

In some other embodiments, referring to FIG. 29, the manufacturing method also includes S500 to S600.
S500: referring to FIG. 27A and FIG. 27B, form a back film 17 on a side of the second substrate 12 close to the reference plane.

In the above step, as shown in FIG. 27A and FIG. 27B, the back film 17 is located in the bonding area D.
S600: remove the part of the second substrate 12 located in the bending area C, the bonding area D, and the second sub-transition area B2, and remove the part of the back film 17 located in the bonding area D, so that the part of the second substrate 12 located in the bending area C, the bonding area D, and the second sub-transition area B2 is reduced in width in the first direction X, and so that the back film 17 is reduced in width in the first direction X.

Here, the first direction X is roughly parallel to the reference plane and roughly perpendicular to a direction from the display area A pointing to the bending area C.

Exemplarily, the part of the second substrate 12 located in the bending area C, the bonding area D, and the second sub-transition area B2, and the part of the back film 17 located in the bonding area D are removed by laser.

The above description is merely the specific implementation of the present disclosure, but the protection scope of the present disclosure is not limited thereto. All changes or substitutions that any person skilled in this art who is familiar with this technology field can think of within the technical scope disclosed by this disclosure, should be covered within the protection scope of the present disclosure. Therefore, the protection scope of the present disclosure should be based on the protection scope of the stated claims.

What is claimed is:

1. A display panel, having a display side and a back side that are disposed opposite each other, wherein the display panel comprises a display area, a bonding area, and a transition area and a bending area that are located between the display area and the bonding area, and the transition area is located between the bending area and the display area;
the display panel further comprises:
a first substrate, wherein the first substrate is a rigid substrate, and the first substrate exposes at least the bending area and the bonding area and covers the display area; and
a second substrate, disposed on a side of the first substrate that is close to the display side of the display panel; wherein the second substrate is a flexible substrate; the second substrate exposes at least a part of the display area and covers the bending area and the bonding area; wherein an orthographic projection of the second substrate on a reference plane partially overlaps with an orthographic projection of the first substrate on the reference plane; and the reference plane is a plane in which a surface of the first substrate away from the second substrate is located.

2. The display panel according to claim 1, wherein the first substrate covers the display area and extends to the transition area; the second substrate covers the bending area and the bonding area and extends to the transition area; and
an orthographic projection of a part of the second substrate located in the transition area on the reference plane overlaps with an orthographic projection of a part of the first substrate located in the transition area on the reference plane.

3. The display panel according to claim 2, wherein the transition area comprises a first sub-transition area and a second sub-transition area, and the first sub-transition area is located between the second sub-transition area and the display area; and
the second substrate comprises a first part and a second part; the first part is located in the second sub-transition area, the bending area, and the bonding area; the second part is located in the first sub-transition area; a width of the first part in a first direction is less than a width of the second part in the first direction; and the first direction is roughly parallel to the reference plane and roughly perpendicular to a direction from the display area pointing to the bending area.

4. The display panel according to claim 1, wherein a length of a part in a second direction where the orthographic projection of the second substrate on the reference plane overlaps with the orthographic projection of the first substrate on the reference plane is 0.25 mm to 3 mm; and the second direction is roughly parallel to the reference plane and is from the display area pointing to the bending area.

5. The display panel according to claim 1, wherein a thickness of the first substrate is 0.1 mm to 0.55 mm; and/or a thickness of the second substrate is 6 μm to 12.5 μm.

6. The display panel according to claim 1, wherein a material of the first substrate comprises one of glass or polymethyl methacrylate; and/or
a material of the second substrate comprises one of polyimide and saturated polyester.

7. The display panel according to claim 1, wherein in a direction perpendicular to the first substrate and extending from the first substrate pointing to the display side of the display panel, the display panel comprises a semiconductor layer, a gate insulating layer, a gate conductive layer, an inter-layer insulating layer, and a first source-drain conductive layer, that are away from the reference plane in sequence;
a vertical distance between a part where an orthographic projection of the gate insulating layer on the reference plane overlaps with the second substrate and the reference plane is a first distance, a vertical distance between a part where an orthographic projection of the gate conductive layer on the reference plane overlaps with the second substrate and the reference plane is a second distance, a vertical distance between a part where an orthographic projection of the inter-layer insulating layer on the reference plane overlaps with the second substrate and the reference plane is a third distance, and a vertical distance between a part where an orthographic projection of the first source-drain conductive layer on the reference plane overlaps with the second substrate and the reference plane is a fourth distance; and a vertical distance between a part where the orthographic projection of the gate insulating layer on the reference plane is misaligned with the second substrate and the reference plane is a fifth distance, a vertical distance between a part where the orthographic projection of the gate conductive layer on the reference plane is misaligned with the second substrate and the reference plane is a sixth distance, a vertical distance between a part where the orthographic projection of the inter-layer insulating layer on the reference plane is misaligned with the second substrate and the reference plane is a seventh distance, and a vertical distance between a part where the orthographic projection of the first source-drain conductive layer on the reference plane is misaligned with the second substrate and the reference plane is an eighth distance;
wherein the first distance is smaller than the fifth distance, the second distance is smaller than the sixth distance, the third distance is smaller than the seventh distance, and the fourth distance is smaller than the eighth distance.

8. The display panel according to claim 1, further comprising:
a first encapsulation layer, wherein the first encapsulation layer is a rigid encapsulation layer; the first encapsulation layer covers at least the display area, and an orthographic projection of the first encapsulation layer on the reference plane is located within a range of the orthographic projection of the first substrate on the reference plane; and
a second encapsulation layer, wherein the second encapsulation layer is a flexible encapsulation layer; and the second encapsulation layer covers the transition area, the bending area and the bonding area.

9. The display panel according to claim 1, further comprises a third encapsulation layer, wherein the third encapsulation layer is a flexible encapsulation layer; and the third encapsulation layer covers the display area, the transition area, the bending area and the bonding area.

10. The display panel according to claim 1, further comprises:
a back film, disposed on a side of the second substrate that is close to the reference plane, and located in the bonding area.

11. A display module, comprising:
the display panel according to claim 1; and
a heat dissipation stacked layer, disposed on the back side of the display panel and covering at least the display area; wherein an orthographic projection of the heat dissipation stacked layer on the reference plane is located within a range of the orthographic projection of the first substrate on the reference plane.

12. A display apparatus, comprising;
the display module according to claim 11; and
a casing, the display module being disposed within the casing.

13. A manufacturing method for a display panel, comprising:
manufacturing a display motherboard; wherein the display motherboard has multiple product areas and multiple cutting areas, and a cutting area of the multiple cutting areas is disposed within a bracket of every two adjacent product areas of the multiple product areas; a product area of the multiple product areas comprises a display area, a bonding area, and a transition area and a bending area located between the display area and the bonding area, and the transition area is located between the bending area and the display area; the display motherboard comprises a first substrate motherboard and a second substrate motherboard, the first substrate motherboard is a rigid substrate motherboard and the first substrate motherboard covers the product area and the cutting area; the second substrate motherboard is a flexible substrate motherboard, the second substrate motherboard is located on the first substrate motherboard, and the second substrate motherboard covers at least the bonding area and bending area and exposes at least a part of the display area;
removing a part of the display motherboard located in the cutting area, to obtain multiple sub-display motherboards; wherein a sub-display motherboard of the multiple sub-display motherboards is located in a product area; and
removing at least a part of the first substrate motherboard of the sub-display motherboard, the part of the first substrate motherboard being located in the bonding area and the bending area, so that a remained part of the first substrate motherboard forms a first substrate and a remained part of the second substrate motherboard forms the second substrate; wherein the first substrate exposes at least the bending area and the bonding area and covers the display area; the second substrate exposes at least a part of the display area and covers the bending area and the bonding area; an orthographic projection of the second substrate on a reference plane partially overlaps with an orthographic projection of the first substrate on the reference plane; the reference plane is a plane in which a surface of the first substrate away from the second substrate is located.

14. The manufacturing method according to claim 13, wherein manufacturing the display motherboard comprises:
providing the first substrate motherboard;
forming a second initial substrate motherboard on the first substrate motherboard, the second initial substrate motherboard covering the product area and the cutting area; and
removing a part of the second initial substrate motherboard located in the display area, so that a remained part of the second initial substrate motherboard forms the second substrate motherboard.

15. The manufacturing method according to claim 14, wherein manufacturing the display motherboard further comprises:
forming a driving circuit stacked layer and a light-emitting stacked layer on the first substrate motherboard and the second substrate motherboard, the light-emitting layer being located on a side of the driving circuit stacked layer away from the first substrate motherboard; and
forming a first encapsulation layer and a second encapsulation layer in sequence on a side of the light-emitting stacked layer away from the first substrate motherboard, wherein the first encapsulation layer is a rigid encapsulation layer; the first encapsulation layer covers at least the display area, and an orthographic projection of the first encapsulation layer on the reference plane is located within a range of the orthographic projection of the first substrate on the reference plane; the second encapsulation layer is a flexible encapsulation layer, and the second encapsulation layer covers the transition area, the bending area, and the bonding area;
or,
forming a driving circuit stacked layer and a light-emitting stacked layer on the first substrate motherboard and the second substrate motherboard, the light-emitting layer being located on a side of the driving circuit stacked layer away from the first substrate motherboard; and
forming a third encapsulation layer on a side of the light-emitting stacked layer away from the first substrate motherboard, wherein the third encapsulation layer is a flexible encapsulation layer, and the third encapsulation layer covers the product area.

16. The manufacturing method according to claim 13, further comprising:
forming a back film on a side of the second substrate that is close to the reference plane; wherein the back film is located in the bonding area.

17. The manufacturing method according to claim 13, further comprising: removing a part of the second substrate located in the bending area, the bonding area, and a second sub-transition area, so that the part of the second substrate located in the bending area, the bonding area, and the second sub-transition area is reduced in width in a first direction; wherein the first direction is roughly parallel to the reference plane and roughly perpendicular to a direction from the display area pointing to the bending area, the transition area comprises a first sub-transition area and the second sub-transition area, and the first sub-transition area is located between the second sub-transition area and the display area; and
the manufacturing method further comprises: in a case where a back film is formed on a side of the second substrate that is close to the reference plane, during removing the part of the second substrate located in the bending area, the bonding area, and the second sub-transition area, further removing a part of the back film located in the bonding area, so that the back film is reduced in width in the first direction.

18. The display panel according to claim 7, further comprises:
a back film, disposed on a side of the second substrate that is close to the reference plane, and located in the bonding area.

19. The display panel according to claim 8, further comprises:
a back film, disposed on a side of the second substrate that is close to the reference plane, and located in the bonding area.

20. The display panel according to claim 9, further comprises:
a back film, disposed on a side of the second substrate that is close to the reference plane, and located in the bonding area.
